(19) United States
(12) Patent Application Publication
(10) Pub. No.: US 2016/0190158 A1
(43) Pub. Date: Jun. 30, 2016

(54) ARRAY SUBSTRATE AND DISPLAY PANEL

(71) Applicant: Shenzhen China Star Optoelectronics Technology Co. Ltd., Shenzhen, Guangdong (CN)

(72) Inventor: Tao SONG, Shenzhen, Guangdong (CN)

(73) Assignee: Shenzhen China Star Optoelectronics Technology Co. Ltd., Shenzhen, Guangdong (CN)

(21) Appl. No.: 14/440,841

(22) PCT Filed: Jan. 21, 2015
(86) PCT No.: PCT/CN2015/071173

§ 371 Date: May 5, 2015

(30) Foreign Application Priority Data
Dec. 30, 2014 (CN) 201410848784.3

(51) Int. Cl. H01L 27/12

(52) U.S. Cl. CPC H01L 27/124

(57) ABSTRACT

The disclosure provides an array substrate and a display panel. The array substrate comprises a display region and a non-display region surrounding the display region comprising a first non-display sub region at one side of the display region. An. integrated circuit chip is arranged in the first non-display sub region. The display region comprises data lines arranged along a first direction, first conductive lines comprising gate lines or common lines and arranged along a second direction, and second conductive lines. A first insulating layer having through holes is arranged between the first conductive lines and the second conductive lines. Each of the first conductive lines electrically connects to one end of the second conductive lines through corresponding through holes, and the other end of the second conductive lines and the data lines electrically connect to the integrated circuit chip. The array substrate has a narrower bezel.

### CROSS REFERENCE TO RELATED APPLICATIONS

This application claims the benefit of, and priority to, Chinese Patent Application No. 201410848784.3, filed Dec. 30, 2014, titled “Array Substrate and Display Panel”, the entire contents of which are incorporated by reference herein in its entirety.

### BACKGROUND OF THE INVENTION

1. Field of the Invention

The disclosure is related to the field of display, and more particularly to an array substrate and a display panel.

2. The Related Arts

With the development of the technology, electrical devices such as mobile phones are widely used. The performance and configuration of the electrical devices such as mobile phones become more and more abundant to satisfy the various needs of users. Narrow bezel is also a new trend introduced. Display panels having narrow bezels may not only increase the usage rate of the display panel but may also increase the perception and user experience. The electrical devices such as mobile phones usually comprise the display panels. The display panel comprises a display region and a non-display region. The display region is usually used to display images, texts or videos. The non-display region is also referred as the bezel region. The non-display region us arranged at the periphery of the display region. The non-display region usually comprises four non-display sub regions arranged adjacent to the top portion, the bottom portion, the left portion and the right portion of the display region. Each non-display sub region is arranged with the circuits or the integrated circuit chip. Therefore, the display panel in the current technology has wider bezel. Thus the perception on the product and the user experience are affected.

### SUMMARY OF THE INVENTION

The present disclosure provides an array substrate such that a display panel comprises the array substrate has a narrower bezel.

The array substrate comprises a display region and a non-display region surrounding the display region, comprising a first non-display sub region at one side of the display region, wherein an integrated circuit chip is arranged in the first non-display sub region; wherein the display region comprises a plurality of data lines arranged along a first direction, a plurality of first conductive lines arranged along a second direction, wherein the first conductive lines comprise gate lines or common lines a plurality of second conductive lines, and a first insulating layer having a plurality of through holes arranged between the first conductive lines and the second conductive lines, wherein each of the first conductive lines electrically connects to one end of the second conductive lines through corresponding through holes, and the other end of the second conductive lines and the data lines electrically connect to the integrated circuit chip.

In one embodiment of the array substrate, the first non-display sub region is arranged corresponding to the bottom of the display region.

The disclosure further provides a display panel having a narrower bezel.

The display comprising an array substrate comprising a display region and a non-display region surrounding the display region, comprising a first non-display sub region at one side of the display region, wherein an integrated circuit chip is arranged in the first non-display sub region; wherein the display region comprises a plurality of data lines arranged along a first direction, a plurality of first conductive lines arranged along a second direction, wherein the first conductive lines comprise gate lines or common lines a plurality of second conductive lines, and a first insulating layer having a plurality of through holes arranged between the first conductive lines and the second conductive lines, wherein each of the first conductive lines electrically connects to one end of the second conductive lines through corresponding through holes, and the other end of the second conductive lines and the data lines electrically connect to the integrated circuit chip.

In one embodiment of the display panel, the first non-display sub region is arranged corresponding to the bottom of the display region.

Comparing with the current technology, in the array substrate of the disclosure, the first insulating layer is arranged on the plurality of the first conductive lines, the second conductive are arranged on the first insulating, a plurality of through holes are arranged on the first insulating layer, the second conductive lines electrically connect to the first conductive lines through the corresponding through holes, and the other end of the second conductive lines and the data lines together electrically connect to the same first non-display sub region. Thus the circuit layout on the non-display sun regions at the two sides of the array substrate is reduced such that the width of the non-display sub region of array substrate is reduced. That is the array substrate has narrower bezel.

### BRIEF DESCRIPTION OF THE DRAWINGS

In order to more clearly illustrate the prior art or the embodiments or aspects of the practice of the disclosure, the accompanying drawings for illustrating the prior art or the embodiments of the disclosure are briefly described as below. It is apparently that the drawings described below are merely some embodiments of the disclosure, and those skilled in the art may derive other drawings according the drawings described below without creative endeavor.

FIG. 1 is a schematic structure of the array substrate according to one embodiment of the disclosure.

FIG. 2 is a schematic cross section view along I-I line in FIG. 1.

FIG. 3 is a schematic structure of the display panel according to one embodiment of the disclosure.

### DETAILED DESCRIPTION OF THE PREFERRED EMBODIMENTS

The following description with reference to the accompanying drawings is provided to clearly and completely explain the exemplary embodiments of the disclosure. It is apparent that the following embodiments are merely some embodiments of the disclosure rather than all embodiments of the disclosure. According to the embodiments in the disclosure, all the other embodiments attainable by those skilled in the art without creative endeavor belong to the protection scope of the disclosure.

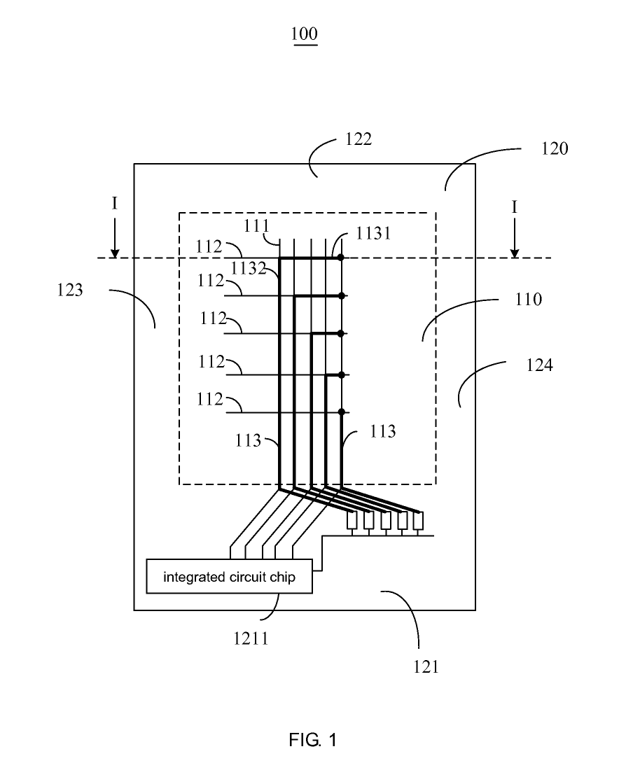

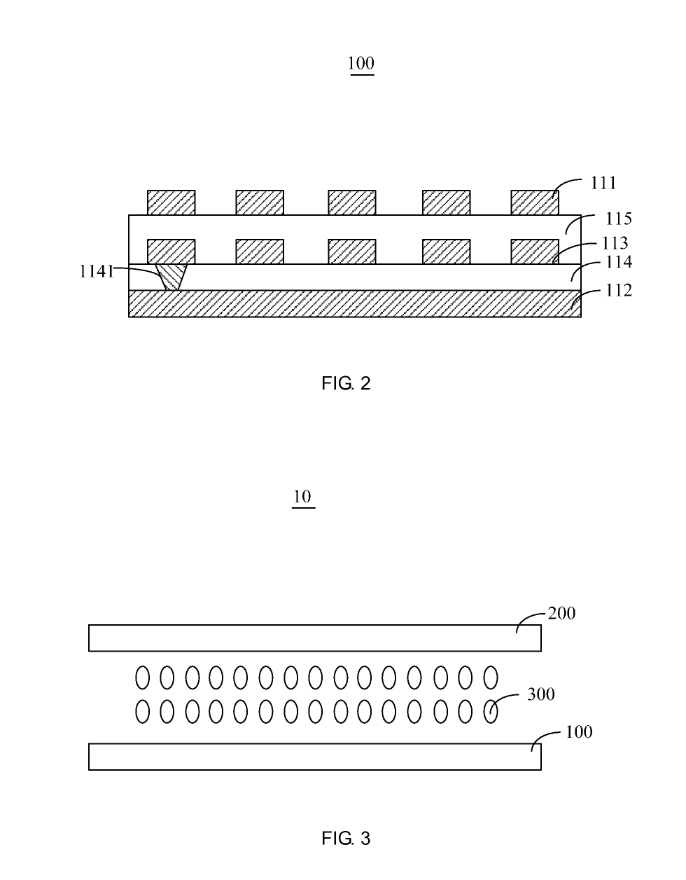

Refer to FIG. 1 and FIG. 2 together. FIG. 1 is a schematic structure of the array substrate according to one embodiment of the disclosure. FIG. 2 is a schematic cross section view along I-I line in FIG. 1. The array substrate 100 comprises a display region 110 and a non-display region 120 surrounding the display region 110. The non-display region 120 comprises a first non-display sub region 121 at one side of the display region 110. An integrated circuit chip 1211 is arranged in the first non-display sub region 121. The integrated circuit chip 1211 is used for generating signals and processing the feedback signals. For example, the integrated circuit chip 1211 may generate scan signals to the gate lines or data signals to the data lines. The display regions 110 comprises a plurality of data lines 111 arranged along a first direction, a plurality of first conductive lines 112 arranged along a second direction, and a plurality of second conductive lines 113. The first conductive lines 112 comprise gate lines or common lines. A first insulating layer 114 having a plurality of through holes 1141 is arranged between the first conductive lines 112 and the second conductive lines 113. Each of the first conductive lines 112 electrically connects to one end of the second conductive lines 113 through corresponding through holes 1141, and the other end of the second conductive lines 113 and the data lines 111 electrically connect to the integrated circuit chip 1121. In this embodiment, the first direction is a vertical direction, and the second direction is a horizontal direction. It may be appreciated that in other embodiments the first direction may be a horizontal direction and the second direction may also be a vertical direction. In other embodiments, the first direction and the second direction may be other directions as long as the first direction and the second direction are two directions that are not parallel.

The material of the second conductive lines 113 may be metal, alloy or transparent conductive material. In one embodiment, the material of the second conductive lines 113 may6 be metal or alloy such that the second conductive lines 113 may have smaller resistance to increase the conductivity of the second conductive lines 113. Transparent conductive material may be arranged in the through holes 1141 such that the first conductive lines 112 may electrically connect to the second conductive lines 113. The transparent conductive lines may be but not limited to Indium Tin Oxides.

The non-display regions 120 further comprises a second non-display sub region 122 opposite to the first non-display sub region 121, and a third non-display sub region 123 and a forth non-display sub region 124. The third non-display sub region 123 and the forth non-display sub region 124 are arranged to be opposite to each other. The two ends of the third non-display sub region 123 connect to the first non-display sub region 121 and the second non-display sub region 122 respectively. The two ends of the forth non-display sub region 124 connect to the first non-display sub region 121 and the second non-display sub region 122 respectively. When the array substrate 100 is applied in an electronic device such as a mobile phone, the first non-display sub region 121 is a non-display region at the bottom of the mobile phone. The first non-display sub region 121 is usually equipped with HOME bottom or a menu bottom. The second non-display sub region 122 corresponds to the top of the mobile phone. The brand sign of the mobile phone is usually arranged on the second non-display sub region 122. The third non-display sub region 123 and the forth non-display sub region 124 are the non-display regions at the two sides of the mobile phone.

At least one of the second conductive lines 113 comprises a first portion 1131 and a second portion 1132 connected to the first portion 1131. The first portion 1131 is arranged along the second direction, and the first portion 1131 is stacked on the first conductive lines 112. The first portion 1131 and the first conductive lines 112 are arranged along the same direction and in a stacked layer manner to reduce the affection on the transmittance when the first portion 1131 and the first conductive lines 112 are not stacked layered (for example the first portion 1131 and the first conductive lines 112 are arranged on the same layer) such that decrease on the transmittance caused by arranging the first portion 1131 on the array substrate 100 may be avoided.

The second portion 1132 is arranged along the first direction, and the second portion 1132 is stacked on the data lines 111. The second portion 1132 and the data lines 111 are arranged along the same direction and in a stacked layer manner to reduce the affection on the transmittance when the second portion 1132 and the data lines 111 are not stacked layered (for example the second portion 1132 and the data lines 111 are arranged on the same layer) such that decrease on the transmittance caused by arranging the second portion 1132 on the array substrate 100 may be avoided.

In this embodiment, the first conductive lines 112, the first insulating layer 114 and the second conductive lines 113 are stacked in sequence. The data lines 111 are arranged on the second conductive lines 113 through a second insulating layer 115. It may be appreciated in another embodiment the first conductive lines 112, the first insulating layer 114 and the second conductive lines 113 are stacked in sequence. The data lines 111 are arranged on a surface of the second conductive lines 113 away from the first insulating layer 114 through a second insulating layer 115.

In one embodiment, the first non-display sub region 121 is arranged corresponding to the bottom of the display region 110.

Comparing with the current technology, in the array substrate 100 of the disclosure, the first insulating layer 114 is arranged on the plurality of the first conductive lines 112, the second conductive 113 are arranged on the first insulating 114, a plurality of through holes 1141 are arranged on the first insulating layer 114, the second conductive lines 113 electrically connect to the first conductive lines 112 through the corresponding through holes 1141, and the other end of the second conductive lines 113 and the data lines 111 together electrically connect to the same first non-display sub region. Thus the circuit layout on the non-display sun regions at the two sides of the array substrate 100 is reduced such that the width of the non-display sub region of array substrate 100 is reduced. That is the array substrate 100 has narrower bezel.

The display panel of the disclosure is introduced as below in conjunction with FIG. 1 and FIG. 2. Refer to FIG. 3. FIG. 3 is a schematic structure of the display panel according to one embodiment of the disclosure. The display panel 10 comprises the array substrate 100 as shown in FIG. 1 and FIG. 2, a color filter substrate 200 and a liquid crystal layer 300. The array substrate 100 and the color filter substrate 200 are arranged opposite. The liquid crystal layer 300 is arranged between the array substrate 100 and the color filter substrate 200.

The array substrate 100 comprises a display region 110 and a non-display region 120 surrounding the display region 110. The non-display region 120 comprises a first non-display sub region 121 at one side of the display region 110. An integrated circuit chip 1211 is arranged in the first non-display sub region 121. The integrated circuit chip 1211 is used for generating signals and processing the feedback signals. For example, the integrated circuit chip 1211 may generate scan signals to the gate lines or data signals to the data lines. The display regions 110 comprises a plurality of data lines 111 arranged along a first direction, a plurality of first conductive lines 112 arranged along a second direction, and a plurality of second conductive lines 113. The first conductive lines 112 comprise gate lines or common lines. A first insulating layer 114 having a plurality of through holes 1141 is arranged between the first conductive lines 112 and the second conductive lines 113. Each of the first conductive lines 112 electrically connects to one end of the second conductive lines 113 through corresponding through holes 1141, and the other end of the second conductive lines 113 and the data lines 111 electrically connect to the integrated circuit chip 1121. In this embodiment, the first direction is a vertical direction, and the second direction is a horizontal direction. It may be appreciated that in other embodiments the first direction may be a horizontal direction and the second direction may also be a vertical direction. In other embodiments, the first direction and the second direction may be other directions as long as the first direction and the second direction are two directions that are not parallel.

The material of the second conductive lines 113 may be metal, alloy or transparent conductive material. In one embodiment, the material of the second conductive lines 113 may6 be metal or alloy such that the second conductive lines 113 may have smaller resistance to increase the conductivity of the second conductive lines 113. Transparent conductive material may be arranged in the through holes 1141 such that the first conductive lines 112 may electrically connect to the second conductive lines 113. The transparent conductive lines may be but not limited to Indium Tin Oxides.

The non-display regions 120 further comprises a second non-display sub region 122 opposite to the first non-display sub region 121, and a third non-display sub region 123 and a forth non-display sub region 124. The third non-display sub region 123 and the forth non-display sub region 124 are arranged to be opposite to each other. The two ends of the third non-display sub region 123 connect to the first non-display sub region 121 and the second non-display sub region 122 respectively. The two ends of the forth non-display sub region 124 connect to the first non-display sub region 121 and the second non-display sub region 122 respectively. When the array substrate 100 is applied in an electronic device such as a mobile phone, the first non-display sub region 121 is a non-display region at the bottom of the mobile phone. The first non-display sub region 121 is usually equipped with HOME bottom or a menu bottom. The second non-display sub region 122 corresponds to the top of the mobile phone. The brand sign of the mobile phone is usually arranged on the second non-display sub region 122. The third non-display sub region 123 and the forth non-display sub region 124 are the non-display regions at the two sides of the mobile phone.

At least one of the second conductive lines 113 comprises a first portion 1131 and a second portion 1132 connected to the first portion 1131. The first portion 1131 is arranged along the second direction, and the first portion 1131 is stacked on the first conductive lines 112. The first portion 1131 and the first conductive lines 112 are arranged along the same direction and in a stacked layer manner to reduce the affection on the transmittance when the first portion 1131 and the first conductive lines 112 are not stacked layered (for example the first portion 1131 and the first conductive lines 112 are arranged on the same layer) such that decrease on the transmittance caused by arranging the first portion 1131 on the array substrate 100 may be avoided.

The second portion 1132 is arranged along the first direction, and the second portion 1132 is stacked on the data lines 111. The second portion 1132 and the data lines 111 are arranged along the same direction and in a stacked layer manner to reduce the affection on the transmittance when the second portion 1132 and the data lines 111 are not stacked layered (for example the second portion 1132 and the data lines 111 are arranged on the same layer) such that decrease on the transmittance caused by arranging the second portion 1132 on the array substrate 100 may be avoided.

In this embodiment, the first conductive lines 112, the first insulating layer 114 and the second conductive lines 113 are stacked in sequence. The data lines 111 are arranged on the second conductive lines 113 through a second insulating layer 115. It may be appreciated in another embodiment the first conductive lines 112, the first insulating layer 114 and the second conductive lines 113 are stacked in sequence. The data lines 111 are arranged on a surface of the second conductive lines 113 away from the first insulating layer 114 through a second insulating layer 115.

In one embodiment, the first non-display sub region 121 is arranged corresponding to the bottom of the display region 110.

Comparing with the current technology, in the array substrate 100 of the disclosure, the first insulating layer 114 is arranged on the plurality of the first conductive lines 112, the second conductive 113 are arranged on the first insulating 114, a plurality of through holes 1141 are arranged on the first insulating layer 114, the second conductive lines 113 electrically connect to the first conductive lines 112 through the corresponding through holes 1141, and the other end of the second conductive lines 113 and the data lines 111 together electrically connect to the same first non-display sub region. Thus the circuit layout on the non-display sun regions at the two sides of the array substrate 100 is reduced such that the width of the non-display sub region of array substrate 100 is reduced. That is the display panel 10 comprising the array substrate 100 has narrower bezel.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. An array substrate, comprising:
a display region; and
a non-display region surrounding the display region, comprising a first non-display sub region at one side of the display region, wherein an integrated circuit chip is arranged in the first non-display sub region;
wherein the display region comprises:
a plurality of data lines arranged along a first direction;
a plurality of first conductive lines arranged along a second direction, wherein the first conductive lines comprise gate lines or common lines;
a plurality of second conductive lines; and
a first insulating layer having a plurality of through holes arranged between the first conductive lines and the second conductive lines, wherein each of the first conductive lines electrically connects to one end of the second conductive lines through corresponding through holes, and the other end of the second conductive lines and the data lines electrically connect to the integrated circuit chip.

2. The array substrate according to claim 1, wherein at least one of the second conductive lines comprises a first portion and a second portion connected to the first portion; the first portion is arranged along the first second direction, and is stacked on the first conductive lines.

3. The array substrate according to claim 2, wherein the second portion is arranged along the first direction and is stacked on the data lines.

4. The array substrate according to claim 1, wherein the first conductive lines, the first insulating layer and the second conductive lines are stacked in sequence; the data lines are arranged on the second conductive lines through a second insulating layer, or the data lines are arranged on a surface of the second conductive lines away from the first insulating layer through a second insulating layer.

5. The array substrate according to claim 1, wherein the first non-display sub region is arranged corresponding to the bottom of the display region.

6. A display panel comprising an array substrate, wherein the array substrate comprises:
a display region; and
a non-display region surrounding the display region, comprising a first non-display sub region at one side of the display region, wherein an integrated circuit chip is arranged in the first non-display sub region;
wherein the display region comprises:
a plurality of data lines arranged along a first direction;
a plurality of first conductive lines arranged along a second direction, wherein the first conductive lines comprise gate lines or common lines;
a plurality of second conductive lines; and
a first insulating layer having a plurality of through holes arranged between the first conductive lines and the second conductive lines, wherein each of the first conductive lines electrically connects to one end of the second conductive lines through corresponding through holes, and the other end of the second conductive lines and the data lines electrically connect to the integrated circuit chip.

7. The display panel according to claim 6, wherein at least one of the second conductive lines comprises a first portion and a second portion connected to the first portion; the first portion is arranged along the first second direction, and is stacked on the first conductive lines.

8. The display panel according to claim 7, wherein the second portion is arranged along the first direction and is stacked on the data lines.

9. The display panel according to claim 6, wherein the first conductive lines, the first insulating layer and the second conductive lines are stacked in sequence; the data lines are arranged on the second conductive lines through a second insulating layer, or the data lines are arranged on a surface of the second conductive lines away from the first insulating layer through a second insulating layer.

10. The display panel according to claim 6, wherein the first non-display sub region is arranged corresponding to the bottom of the display region.
